(19) United States
(12) Patent Application Publication
(10) Pub. No.: US 2025/0370349 A1
(43) Pub. Date: Dec. 4, 2025

(54) CONTROL INTERFACE OF MASK SENSING ASSEMBLY

(71) Applicant: MICROPROGRAM INFORMATION CO., LTD., Taichung (TW)

(72) Inventor: TENG YEN WU, Taichung (TW)

(21) Appl. No.: 19/200,154

(22) Filed: May 6, 2025

(30) Foreign Application Priority Data
May 31, 2024 (TW) 113120263

(51) Int. Cl. G03F 7/00

(52) U.S. Cl. CPC G03F 7/70508; G03F 7/7085; G03F 7/70866; G03F 7/70991

(57) ABSTRACT

A mask sensing assembly comprises a mask-like sensing module and a housing. The mask-like sensing module has a sensor and a storage unit. The sensor senses environment information in a simulating lithography process and generates a sensing signal to be stored in the storage unit. The housing, which is designated to receive the mask-like sensing module, has a housing processor, a plurality of control buttons and indicators. The control buttons are manipulated to generate a predetermined command, and the command is transmitted to the mask-like sensing module in a wireless way to execute the command. The mask-like sensing module generates a status signal after the command is executed, and the status signal is transmitted back to the housing to control the indicators showing specified message accordingly.

### BACKGROUND OF THE INVENTION

The present invention relates to semiconductor manufacturing processes, and more particularly to a control interface configured to control and transmit data to a photomask sensing assembly.

In current semiconductor manufacturing processes, the lithography process is one of the indispensable key steps. Specifically, the lithography process involves projecting a light source of a specific wavelength, allowing the light source to pass through a mask (also known as photomask or reticle) and irradiate a photoresist on a wafer, thereby inducing chemical changes in the photoresist and transferring a circuit pattern from the mask onto the wafer.

The mask plays a critical role in the lithography process. Generally, the mask is a thin sheet made of quartz glass, on which a circuit pattern is formed by arranging a specific metal coating (such as a chromium metal layer) in a predetermined configuration. However, similar to a wafer, a mask is a precise and fragile carrier. A common issue is that the material and structural strength of the mask are inherently fragile; therefore, any vibration or tilting occurring during transportation or within the lithography process may adversely affect the structure of the mask. On the other hand, the mask itself and the metal coating thereon may deteriorate, deform, or become brittle due to variations in environmental temperature and humidity. The aforementioned issues may impact the performance of the mask, and once a mask is compromised, the wafers fabricated using the mask may also be adversely affected and rendered unusable, leading to potentially incalculable losses for semiconductor manufacturers.

U.S. Patent Publication No. 2024/0302733, which is the inventors' prior invention, disclosed a reticle-like sensing assembly, which is capable of simulating the transportation process and fabrication process of a mask in an offline environment and sensing related environmental information, thereby detecting any abnormalities in the working environment or equipment. Although that invention provides a solution for detecting environmental information during the lithography process, there remains room for improvement regarding the control of the sensing assembly and the transmission of data.

### SUMMARY OF THE INVENTION

In view of the above, the primary object of the present invention is to provide a control interface of mask sensing assembly, which offers a solution for controlling the mask sensing assembly and transmitting data therefrom.

In order to achieve the objective of the present invention, the present invention discloses a mask sensing assembly, comprises a mask-like sensing module and a housing. The mask-like sensing module has a body with a shape identical to that of an actual mask, the body being provided with a sensor, a power source, a processor, a storage unit, a wireless charging receiver, and a first transceiver; wherein the sensor is configured to sense environmental information of the body during a simulated lithography process and to generate a sensing signal accordingly; wherein the processor is configured to stores the sensing signal in the storage unit; wherein the power source is configured to supplies electrical power to the sensor, the processor, the storage unit, and the first transceiver; wherein the wireless charging receiver is electrically connected to the power source; wherein the first transceiver is configured to wirelessly receive or transmit signals. The housing has a carrying area to place the mask-like sensing module thereon, the housing further comprises a housing processor, a housing power source, a wireless charging transmitter, and a housing transceiver; wherein the housing power source is configured to supplies electrical power to the wireless charging transmitter for wireless charging; thereby when the mask-like sensing module is placed on the carrying area, the wireless charging transmitter is aligned with the wireless charging receiver to transmit a power signal for charging the power source. Wherein the housing further comprises an interface area provided with a plurality of control buttons and indicators; the housing processor is electrically connected to the control buttons to receive and process commands generated by the control buttons and transmit the commands via the housing transceiver and the first transceiver to the processor of the mask-like sensing module for execution; after the command is executed, the processor of the mask-like sensing module generates a status signal transmitted to the housing processor via the first transceiver and the housing transceiver to control the indicators showing specified message accordingly.

In an embodiment, further comprising a terminal having a terminal transceiver; the mask-like sensing module including a second transceiver communicated with the terminal transceiver; the terminal being configured to generate a command transmitted to the mask-like sensing module via the terminal transceiver and the second transceiver, so as to control the processor to read the sensing signal stored in the storage unit and transmitted back to the terminal via the second transceiver and the terminal transceiver for processing and analysis.

In an embodiment, the second transceiver of the mask-like sensing module is wireless connected to the terminal transceiver of the terminal.

In an embodiment, the first transceiver of the mask-like sensing module is wireless connected the housing transceiver of the housing.

In an embodiment, the control buttons include a sensor on/off button; when short-pressing the sensor on/off button, the mask-like sensing module is power on and enters a standby state, while when long-pressing the sensor on/off button, the mask-like sensing module is power off.

In an embodiment, the control buttons include a start record button and a stop record button; when pressing the start record button, the sensor of the mask-like sensing module starts to detect the environmental information, while when pressing the stop record button, the sensor of the mask-like sensing module stops from detecting the environmental information.

In an embodiment, the control buttons include a check status button; when pressing the check status button, the housing and the mask-like sensing module check their current statuses and causes the indicators to display the statuses of the housing and the mask-like sensing module.

In an embodiment, the environmental information detected by the sensor includes at least one of temperature, humidity, vibration, and tilt angle.

In an embodiment, the housing power source includes an internal battery and a power cable, the internal battery is configured to supply electrical power required by the housing processor, the housing transceiver, and the indicators, and the power cable is connected to an external power source to charge the internal battery and to provide the electrical power required for the wireless charging transmitter to perform wireless charging.

In an embodiment, the housing includes a base and a cover, and a top surface of the base is provided with the carrying area and the interface area.

A preferred embodiment is described hereafter, accompanied with drawings, according to the objective and function of the present invention.

### BRIEF DESCRIPTION OF DRAWINGS

FIG. 1 is an exploded view of a preferred embodiment of the present invention;

FIG. 2 is a block view of the preferred embodiment of the present invention; and

FIG. 3 is a front view of the interface area of the preferred embodiment of the present invention.

### DETAILED DESCRIPTION OF THE INVENTION

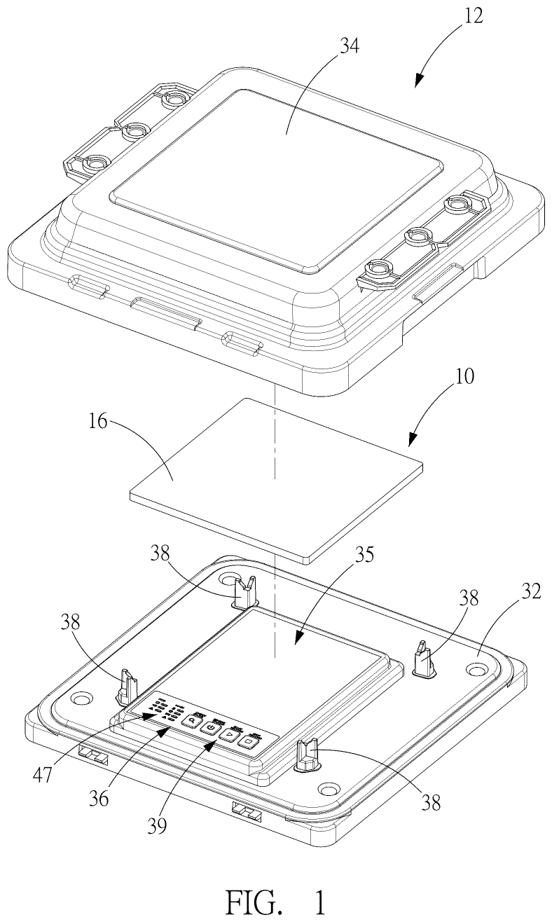

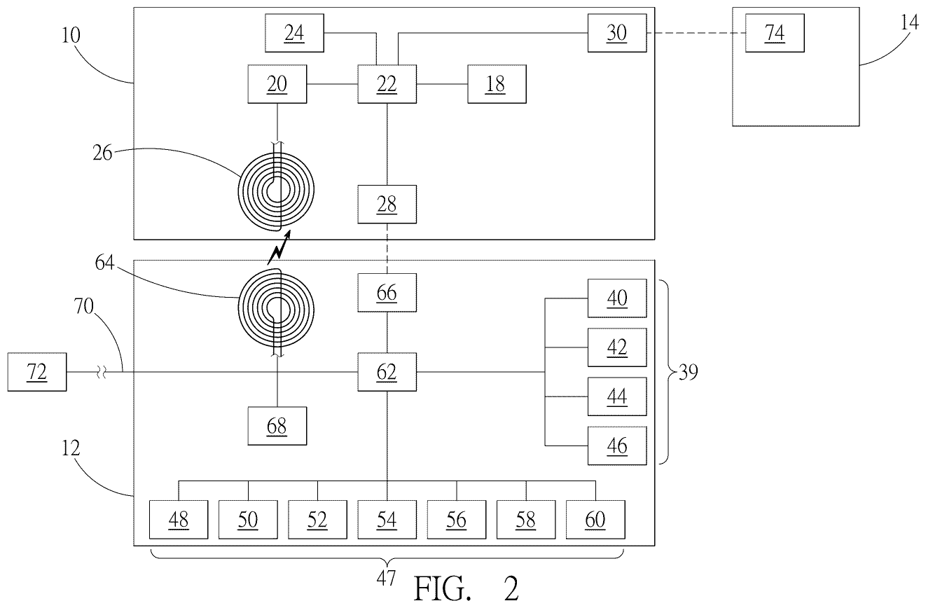

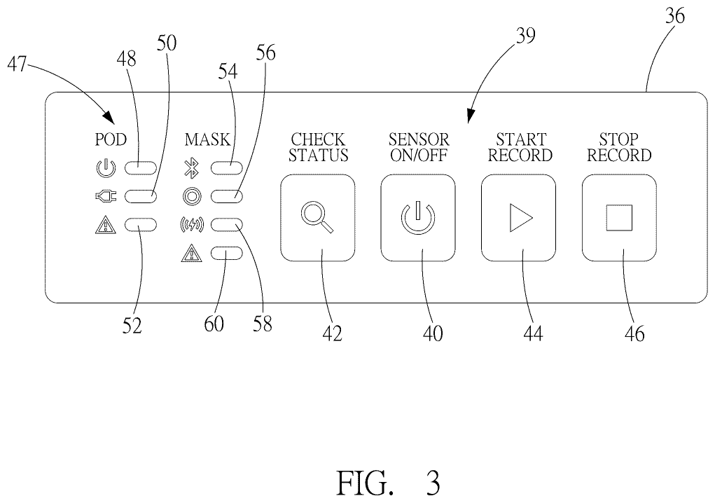

As shown in FIG. 1 to FIG. 3, a mask sensing assembly of a preferred embodiment of the present invention comprises a mask-like sensing module 10, a housing 12, and a terminal 14.

The mask-like sensing module 10 has a body 16 configured to have an external shape identical to that of an actual mask. The body 16 is provided with a sensor 18, a power source 20, a processor 22, a storage unit 24, a wireless charging receiver 26, a first transceiver 28, and a second transceiver 30. The aforementioned components are electrically connected through a circuit of a circuit board (not shown). The sensor 18 is configured to sense environmental information of the body 16 during a simulated lithography process, including temperature, humidity, vibration, and tilt angle, so as to generate a sensing signal accordingly. The processor 22, electrically connected to the sensor 18, is configured to command the sensor 18 to start or stop detecting the environmental information and to store the sensing signal in the storage unit 24. The power source 20 is configured to supply an electrical power required by the aforementioned components. The wireless charging receiver 26, electrically connected to the power source 20, is configured to charge the power source 20. The first transceiver 28 and the second transceiver 30 are respectively electrically connected to the processor 22 and are configured to wirelessly receive or transmit signals (e.g., via Wi-Fi, Bluetooth, Zigbee, infrared, radio frequency signal, etc.).

The housing 12 includes a base 32 and a cover 34. A top surface of the base 32 is provided with a carrying area 35 and an interface area 36. A plurality of support columns 38 is disposed at the carrying area 35 for placing the mask-like sensing module 10 thereon. The interface area 36 is provided with a plurality of control buttons 39 and indicators 47.

An interior of the base 32 is equipped with a housing processor 62, a housing power source, a wireless charging transmitter 64, and a housing transceiver 66. The aforementioned components are electrically connected through a circuit of a circuit board. In the present preferred embodiment, the housing power source includes an internal battery 68 for supplying power to the aforementioned components, and a power cable 70 for connecting to an external power source 72 (such as mains power or a battery pack). When the power cable 70 is connected to the external power source 72, the internal battery 68 can be charged, and electrical power required for wireless charging can be supplied to the wireless charging transmitter 64.

The wireless charging transmitter 64 is disposed beneath the carrying area 35. When the mask-like sensing module 10 is placed on the support columns 38 of the carrying area 35, the wireless charging transmitter 64 is aligned with the wireless charging receiver 26 to wirelessly transmit a power signal. The wireless charging transmitter 64 and the wireless charging receiver 26 are conventional components capable of transmitting power in a non-contact manner, and thus the detailed structure thereof is omitted herein for brevity.

The housing processor 62 is electrically connected to the housing transceiver 66, and is configured to transmit specific signals to the mask-like sensing module 10 via the housing transceiver 66 and the first transceiver 28, or to receive signals transmitted from the mask-like sensing module 10. In the present preferred embodiment, signals between the housing transceiver 66 and the first transceiver 28 are transmitted via a radio frequency signal.

The control buttons 39 are electrically connected to the housing processor 62 and are operated to transmit predetermined commands to the housing processor 62. The commands are then transmitted to the mask-like sensing module 10 via the housing transceiver 66 and the first transceiver 28, instructing the processor 22 of the mask-like sensing module 10 to perform corresponding actions. After executing the commands, the processor 22 of the mask-like sensing module 10 generates a status signal, which is transmitted back to the housing processor 62 through the first transceiver 28 and the housing transceiver 66. The housing processor 62 then controls the indicators 47 to display specific information accordingly.

In the present preferred embodiment, the control buttons 39 include a sensor on/off button 40, a check status button 42, a start record button 44, and a stop record button 46. The indicators 47 are a plurality of LED lights, including a housing power indicator 48, an external power connection indicator 50, a housing fault indicator 52, a sensing indicator 54, a signal connection indicator 56, a wireless charging indicator 58, and a sensing module fault indicator 60.

The terminal 14 is a computer, such as a desktop computer, a laptop, a tablet, or a smartphone. The terminal 14 is provided with a terminal transceiver 74 configured to communicate with the second transceiver 30 of the mask-like sensing module 10. The terminal transceiver 74 and the second transceiver 30 are configured to wirelessly receive or transmit information (e.g., via Wi-Fi, Bluetooth, Zigbee, infrared, radio frequency signal, etc.). In the present preferred embodiment, the terminal transceiver 74 and the second transceiver 30 communicate via Bluetooth.

The terminal 14 can generate a command, which is transmitted to the mask-like sensing module 10 via the terminal transceiver 74 and the second transceiver 30, instructing the processor 22 to receive the sensing signals stored in the storage unit 24 and to transmit the sensing signals back to the terminal 14 through the second transceiver 30 and the terminal transceiver 74 for processing and analysis.

In an alter preferred embodiment, the terminal transceiver 74 and the second transceiver 30 are connection ports (e.g., USB ports), and a transmission cable (not shown) is used to connect the mask-like sensing module 10 to the terminal 14.

By means of the above structure, a user can operate the control buttons 39 on the housing 12 to perform wireless operations through the wireless transceivers of the housing 12 and the mask-like sensing module 10, without causing any interference with the sensing process. The control functions of the control buttons 39 are described as follows:
1. Press any one of the control buttons 39: the housing 12 is powered on and switched to a standby state.
2. Short pressing the sensor on/off button 40: the mask-like sensing module 10 is powered on and switches to a standby state.
3. Long pressing the sensor on/off button 40: the mask-like sensing module 10 is powered off.
4. Pressing the start record button 44: the mask-like sensing module 10 starts detecting environmental information, generates the sensing signal accordingly, and stores the sensing signal in the storage unit 24.
5. Pressing the stop record button 46: the mask-like sensing module 10 stops detecting.
6. Pressing the check status button 42: the current statuses of the mask-like sensing module 10, the housing 12, and the terminal 14 are checked.

When the mask sensing assembly of the present preferred embodiment executes various commands, the indicators 47 will display the procedure accordingly. The meanings represented by the respective indicators 47 are as follows:
1. The housing power indicator 48: indicates that the housing 12 is powered on.
2. The external power connection indicator 50: indicates that the power cable 70 is connected to the external power source 72.
3. The housing fault indicator 52 (steady on): indicates that the housing 12 has a malfunction.
4. The housing fault indicator 52 (flashing): indicates that the housing 12 has low battery power.
5. The sensing indicator 54: indicates that the sensor 18 of the mask-like sensing module 10 is detecting environmental information.
6. The signal connection indicator 56 (steady on): indicates that the terminal transceiver 74 of the terminal 14 is connected to the second transceiver 30 of the mask-like sensing module 10.
7. The signal connection indicator 56 (flashing): indicates that the mask-like sensing module 10 is transmitting the sensing signal to the terminal 14.
8. The wireless charging indicator 58: indicates that the power source 20 of the mask-like sensing module 10 is being wirelessly charged.
9. The sensing module fault indicator 60 (steady on): indicates that the mask-like sensing module 10 has a malfunction.
10. The sensing module fault indicator 60 (flashing): indicates that the mask-like sensing module 10 has low battery power.

By means of the structure disclosed in the present preferred embodiment, the user can operate the control buttons 39 on the housing 12 to wirelessly control the mask-like sensing module 10 and observe the indicators 47 to obtain the current status. Additionally, by issuing a command from the terminal 14, the sensing signals stored in the mask-like sensing module 10 can be downloaded, enabling the terminal 14 to process and analyze the data in order to understand the condition of the mask throughout the lithography process.

It must be pointed out that the embodiments described above are only some preferred embodiments of the present invention. All equivalent structures which employ the concepts disclosed in this specification and the appended claims should fall within the scope of the present invention.

1. A mask sensing assembly, comprising:
a mask-like sensing module having a body with a shape identical to that of an actual mask, the body being provided with a sensor, a power source, a processor, a storage unit, a wireless charging receiver, and a first transceiver; wherein the sensor is configured to sense environmental information of the body during a simulated lithography process and to generate a sensing signal accordingly; wherein the processor is configured to stores the sensing signal in the storage unit; wherein the power source is configured to supplies electrical power to the sensor, the processor, the storage unit, and the first transceiver; wherein the wireless charging receiver is electrically connected to the power source; wherein the first transceiver is configured to wirelessly receive or transmit signals; and
a housing having a carrying area to place the mask-like sensing module thereon, the housing further comprising a housing processor, a housing power source, a wireless charging transmitter, and a housing transceiver; wherein the housing power source is configured to supplies electrical power to the wireless charging transmitter for wireless charging; thereby when the mask-like sensing module is placed on the carrying area, the wireless charging transmitter is aligned with the wireless charging receiver to transmit a power signal for charging the power source;
wherein the housing further comprises an interface area provided with a plurality of control buttons and indicators; the housing processor is electrically connected to the control buttons to receive and process commands generated by the control buttons and transmit the commands via the housing transceiver and the first transceiver to the processor of the mask-like sensing module for execution; after the command is executed, the processor of the mask-like sensing module generates a status signal transmitted to the housing processor via the first transceiver and the housing transceiver to control the indicators showing specified message accordingly.

2. The mask sensing assembly of claim 1, further comprising a terminal having a terminal transceiver; the mask-like sensing module including a second transceiver communicated with the terminal transceiver; the terminal being configured to generate a command transmitted to the mask-like sensing module via the terminal transceiver and the second transceiver, so as to control the processor to read the sensing signal stored in the storage unit and transmitted back to the terminal via the second transceiver and the terminal transceiver for processing and analysis.

3. The mask sensing assembly of claim 2, wherein the second transceiver of the mask-like sensing module is wireless connected to the terminal transceiver of the terminal.

4. The mask sensing assembly of claim 1, wherein the first transceiver of the mask-like sensing module is wireless connected the housing transceiver of the housing.

5. The mask sensing assembly of claim 1, wherein the control buttons include a sensor on/off button; when short-pressing the sensor on/off button, the mask-like sensing module is power on and enters a standby state, while when long-pressing the sensor on/off button, the mask-like sensing module is power off.

6. The mask sensing assembly of claim 1, wherein the control buttons include a start record button and a stop record button; when pressing the start record button, the sensor of the mask-like sensing module starts to detect the environmental information, while when pressing the stop record button, the sensor of the mask-like sensing module stops from detecting the environmental information.

7. The mask sensing assembly of claim 1, wherein the control buttons include a check status button; when pressing the check status button, the housing and the mask-like sensing module check their current statuses and causes the indicators to display the statuses of the housing and the mask-like sensing module.

8. The mask sensing assembly of claim 1, wherein the environmental information detected by the sensor includes at least one of temperature, humidity, vibration, and tilt angle.

9. The mask sensing assembly of claim 1, wherein the housing power source includes an internal battery and a power cable, the internal battery is configured to supply electrical power required by the housing processor, the housing transceiver, and the indicators, and the power cable is connected to an external power source to charge the internal battery and to provide the electrical power required for the wireless charging transmitter to perform wireless charging.

10. The mask sensing assembly of claim 1, wherein the housing includes a base and a cover, and a top surface of the base is provided with the carrying area and the interface area.
